(19) United States
(12) Patent Application Publication
(10) Pub. No.: US 2005/0235915 A1
(43) Pub. Date: Oct. 27, 2005

(54) Plasma surface treatment electrode assembly and arrangement

(76) Inventors: Yeu-Chuan Simon Ho, Naperville, IL (US); Robert Sever, Arlington Heights, IL (US); Balazs Hunek, Chicago, IL (US); Jeffrey Richard Wallace, Naperville, IL (US)

Correspondence Address: PRAXAIR, INC.;LAW DEPARTMENT - M1 557, 39 OLD RIDGEBURY ROAD, DANBURY, CT, 06810-5113, US

(21) Appl. No.: 10/832,447

(22) Filed: Apr. 27, 2004

(51) Int. Cl. C23C 16/00

(52) U.S. Cl. 118/723 E; 156/345.43

(57) ABSTRACT

An electrode assembly for an arrangement of electrodes used in a plasma surface treatment apparatus. The electrode assembly includes an electrode body formed of a dielectric material and having two spaced end walls. One or more flow channels are defined between the end walls for passage of cooling fluid to cool the electrode body. The flow channel(s) are configured such that a direct flow path exists for the cooling fluid from one of the end walls to the other of the two end walls to inhibit recirculation of the cooling fluid and therefore hot spots developing in the electrode body. Openings within the end walls are provided for passage of the cooling fluid. A high voltage conductor is located within the flow passage(s) so that heat produced at the high voltage conductor is dissipated by the cooling fluid.

### FIELD OF THE INVENTION

The present invention relates to an electrode assembly that forms an arrangement of one or more electrodes of a plasma surface treatment apparatus in which a substrate is treated by a non-equilibrium plasma generated between an active electrode and a counter or ground electrode. More particularly, the present invention relates to such an electrode assembly in which a direct flow path is provided for cooling fluid within a cavity of the electrode assembly to inhibit recirculation of the cooling fluid within the cavity.

### BACKGROUND OF THE INVENTION

Non-equilibrium plasma, produced by uniform glow discharges, is utilized for the surface treatment of polymer films, fabrics, wool, metal, and paper to improve the physical and optical properties of the surface. Such properties include printability, wetability, durability, and adhesion of coatings.

The non-equilibrium plasma is generated within a thin gap between two electrodes. The gap is generally less than about two millimeters. A high voltage is applied to an active electrode. The active electrode is formed of an electrode assembly having a electrode body made of a dielectric material. The electrode body contains and a high voltage conductor to which the high voltage is applied. The dielectric material, which can be a ceramic or glass, ensures the uniformity of the discharge. A grounded, counter electrode is positioned opposite to the active electrode and can be in the form of a rotating drum or a flat plate or can have a similar configuration to the active electrode. As such, the counter electrode can also be in the form of a high voltage conductor encased in a dielectric. A plasma medium, which can be helium or other gas or a mixture of gases, is injected into the region between the two electrodes to generate the non-equilibrium plasma.

The substrate, which is in sheet form, is passed between the active and counter electrodes to be treated by the non-equilibrium plasma. The active components of the plasma interact with surface or bulk characteristic of the substrate. Potential surface interactions include chemical transformations of the surface functional groups, material deposition and surface cleaning or sterilization. Bulk interactions include the transformation or destruction of chemical or biological components.

During generation and maintenance of the non-equilibrium plasma, the thermal cycle introduced by electromagnetic power deposition can lead to thermal failure of the electrode assembly, the substrate being processed, or the plasma itself. Potential types of thermal failure for the electrode assembly or substrate include fatigue cracking, thermal or mechanical distortion, thermal or mechanical stressing, binding failure and flow erosion. Uncontrolled thermal instabilities can cause the plasma to transition from a low temperature, non-equilibrium regime (in which the kinetic temperature of the electrons can exceed the neutral gas temperature by over two orders of magnitude) to a high temperature, thermal regime in which the plasma approaches local thermal equilibrium.

Thermal instabilities can also cause the transition from a uniform flow discharge to a highly localized filamentary or arc plasma which is incapable of providing uniform surface or bulk treatment. Furthermore, improper control of plasma component temperatures directly impacts important operating characteristics, such as plasma number density, electric field strength, electron absorbed power density, surface and bulk reaction kinetics, concentration of reactive species (ions, electrons, neutrals, metastables), turbulent reaction flow and plasma processing rate.

In order to maintain a stable non-equilibrium plasma discharge at near atmospheric pressure, the electrodes between which that plasma is generated must be cooled by dissipating the heat produced at the high voltage conductor. This cooling provides adequate thermal reliability for a particular duty cycle. In addition, thermal distortion of the electrodes is minimized while avoiding excessive heat. The particular cooling strategy utilized must provide a sufficient heat transfer rate to meet the system cooling requirements to optimize coolant velocities and thereby maximize heat transfer.

U.S. Pat. No. 6,429,525 discloses a plasma surface treatment apparatus employing electrode assemblies in the form of two hollow, air cooled active electrodes located opposite to a rotating, cylindrical counter electrode. Each of the active electrodes has a body of generally rectangular cross-section that contains a strip-like high voltage conductor. Compressed air passes from a single inlet at one end of the hollow electrode and is discharged from a single outlet located at the other end thereof. The inlet and outlet are located in the side of the electrodes. As a result, the cooling fluid must change direction when flowing from the inlet to the outlet. This change in direction can produce recirculation of cooling fluid within the electrode.

The single inlet and outlet configuration coupled with the lack of direct flow path for the cooling fluid results in recirculation zones within the electrode body and therefore uneven heating and hot spots. As will be discussed, the present invention solves this problem so that the electrode assembly is uniformly cooled by inhibiting the formation of recirculation zones within the electrode body of the electrode assembly.

### SUMMARY OF THE INVENTION

In one aspect, the present invention provides an electrode assembly for a plasma surface treatment apparatus for treating a surface of an article. In accordance with the present invention, an electrode body formed of a dielectric material is provided. The electrode body has two end walls spaced apart from one another. At least one flow channel is defined between the end walls for passage of cooling fluid to cool the electrode body. The at least one flow channel is configured such that a direct flow path exists for the cooling fluid from one of the two end walls to the other of the two end walls to inhibit recirculation of the cooling fluid and therefore hot spots developing in the electrode body. Openings are defined within the end walls to introduce and discharge the cooling fluid to and from the at least one flow channel, respectively.

A high voltage conductor is located within the at least one flow passage and bounds part of the at least one flow passage so that the dielectric material forms a barrier between the surface of the article and the high voltage conductor when the electrode is in use and heat produced at the high voltage conductor is dissipated by the cooling fluid.

The electrode body can be provided with ribs within the at least one flow channel such that the at least one flow channel is a plurality of flow channels. The openings are arranged so that each of said flow channels has a corresponding pair of openings for the flow of the cooling fluid within each of said flow channels. Alternatively, the at least one flow channel can be one flow channel.

In any embodiment of the present invention, the at least one flow channel and the two end walls each have a rectangular transverse cross-section. In such embodiment the high voltage conductor is of plate-like configuration and the openings are arranged in an array across the rectangular transverse cross-section of the two end walls.

The electrode assembly can further be provided with one or more flow deflectors situated in the one or plurality of flow channels, respectively, to deflect the flow of the cooling fluid toward the high voltage conductor. Further, preferably, the high voltage conductor is brazed to the electrode body.

In another aspect of the present invention an arrangement of electrode assemblies for treating a substrate is provided. In such aspect, a high voltage is applied to an active electrode and a ground electrode spaced from the active electrode to allow the substrate to pass therebetween. Each of the active electrode and the ground electrode is formed of an electrode assembly that has the features described above. Further, the active electrode and the ground electrode can share the sidewalls of each electrode body associated therewith to form a slot-like opening between the sidewalls and the active electrode and ground electrode.

### BRIEF DESCRIPTION OF THE DRAWINGS

While the specification concludes with claims distinctly pointing out the subject matter that Applicants regard as their invention, it is believed that the invention would be better understood when taken in connection with the accompanying drawings in which:

FIG. 1 is a schematic perspective view of an electrode in accordance with the present invention in which portions have been broken away to illustrate internal components thereof;

FIG. 2 illustrates an alternative method of using the electrode assembly shown in FIG. 1;

FIG. 3 is a schematic plan view of a manifold attached to the electrode assembly of FIG. 1, illustrated in a fragmentary plan, sectional view, that is used to feed the cooling fluid to such electrode assembly;

FIG. 4 is a schematic, sectional view of an inlet manifold used in feeding cooling fluid to the electrode of FIG. 2;

FIG. 5 is a schematic, sectional view of a manifold used in connection with the electrode illustrated in FIG. 2; and

FIG. 6 is a sectional view of the flow channels utilized in the electrode assembly of either FIG. 1 taken along line 6-6 of FIG. 1.

### DETAILED DESCRIPTION

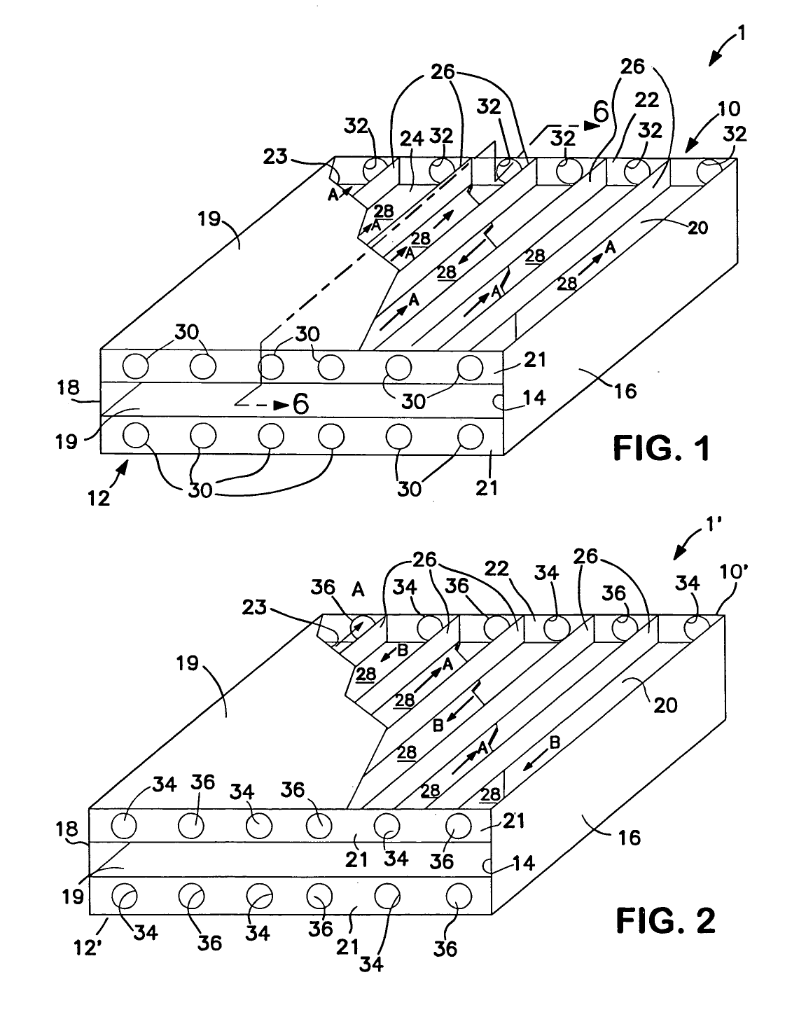

With reference to FIG. 1, an arrangement 1 of electrodes in accordance with the present invention is illustrated. Arrangement 1 includes an electrode assembly 10 which can be connected to a high frequency current source and a counter electrode that is formed of an electrode assembly 12 that is grounded. A substrate formed of sheet-like material to be treated is passed within a slot-like enclosed area 14 that is bounded by electrode assemblies 10 and 12 and sidewalls 16 and 18 thereof. Although not illustrated, the arrangement 1 of electrodes would be positioned within a chamber to which a plasma medium such as helium would be introduced. The chamber in a known manner would have a slot for passage of the substrate into the electrode assembly. The plasma medium through application of a high voltage to the electrode assemblies would in a known manner produce a non-equilibrium plasma to treat the substrate.

Electrode assembly 10 has a electrode body of box-like configuration that is formed of dielectric material that is defined by two opposed plate-like elements 19 and 20, a portion of sidewalls 16 and 18 and end walls 21 and 22. Within a region of the electrode body defined between plate-like elements 18 and 20, sidewalls 16 and 18, and end walls 20 and 22, a cavity 23 is formed that is bounded at the bottom by a plate-like high voltage conductor 24. The high voltage is applied to high voltage conductor 24.

It is to be noted that high voltage conductor 24 can be attached to plate-like element 20 of the electrode body of electrode assembly 10 by a suitable adhesive or by braising. In this regard to obtain excellent hermetic properties and reduce problems related to voids and thermal expansion, the high voltage conductor 24 and dielectric barrier surfaces are assembled with the necessary brazing assembly materials. The brazing solder materials can be pre-applied to the individual piece in the quantities required for selected metal and dielectric materials. Typical materials used for an electrode assembly in accordance with the present invention and brazing solder combinations are listed in the table below.

TABLE

| High voltage | | Dielectric |
|---|---|---|
| conductor 24 | Brazing-solder | Material |
| Cu | AgCu 28% | SiO2 |
| Fe/Ni | AgCu 15% | Si3N4 |
| Kov | AgGe 13% | Al2O3 |
| Fe/N142 | AgSn 20% | TiO2, Ta2O5 |

For compatibility with highly diversified substrates during thermal expansion for thin electrodes, the high voltage conductors can be deposited directly on the dielectric surface using metal pastes such as Cu paste, Ag/Cu paste, and Ag/Pt paste etc. Selected powders used in the pastes can produce remarkably thick and dense film on the dielectric surfaces.

The cavity 23 described above contains ribs 26 that form flow channels 28. Flow channels 28 are bounded at opposite ends by the end walls 19 and 20. A cooling fluid, which could be the plasma medium for instance, helium, is passed into flow channels 28 for dissipating heat produced at the plate-like high voltage conductor 24 in order to cool electrode assembly 10. An array of a plurality of openings 30, extending across end wall 19 are provided to introduce the cooling fluid in the direction of the arrowheads “A” into the flow channels 28. The cooling fluid is expelled from an array of a plurality of openings 32 extending across end wall 20. As illustrated one pair of openings 30 and 32 is associated with each of the flow channels 28. In such manner, a direct flow path is produced within flow channels 28 that will inhibit recirculation of the cooling fluid within electrode assembly 10 since the flow enters flow channels 28 from end wall 19 and is discharged from end wall 20 that are located at opposite ends of the flow channels 28.

Electrode assembly 12 is of identical design to electrode assembly 10. It is understood, however, that electrode assemblies in accordance with the present invention could be of any shape or incorporated into any arrangement of electrodes. For instance, electrode assembly 10 could be used in connection with a counter or ground electrode that was formed of a flat plate. Furthermore, electrode assembly 10 or 12 for that matter could be curved.

With reference to FIG. 2, an alternative method of using arrangement 1 of electrodes in accordance with the present invention is illustrated which is identical to arrangement 1. In such embodiment, however, the introduction and discharge of cooling fluid alternate across the end walls 19 and 20. In this regard, openings 30 and 32 and openings 34 and 36 are all identical openings. Such numbering is used for purposes of illustration only. However, as indicated by the arrowheads “A” and “B”, the flow within flow channels 28 will be countercurrent due to the alternating inlet of cooling fluid into openings 34 and the discharge from openings 36. The flow within electrode assembly 10 which is all in the same direction of arrowhead “A” and is thus, cocurrent. These flow patterns can be produced by manifolds described below.

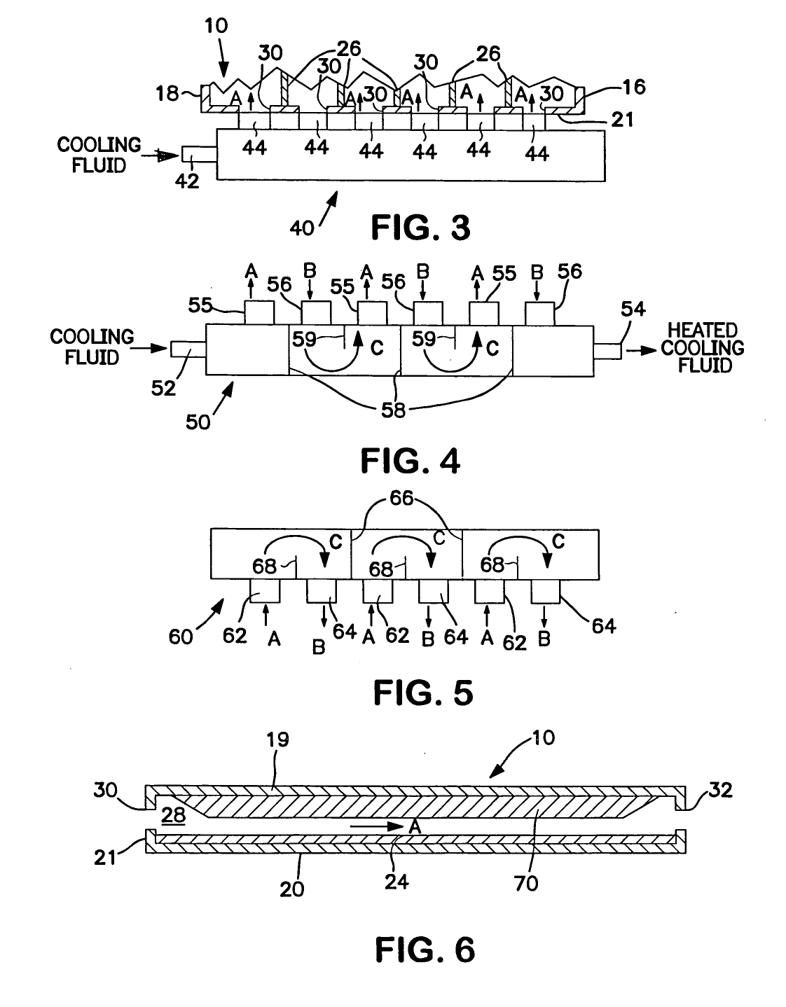

With reference to FIG. 3, in order to produce the cocurrent flow within electrode assembly 10 or electrode assembly 12 for that matter, electrode assembly can further be provided with an inlet manifold 40 having a manifold inlet 42 and manifold openings 44. The manifold openings 44 are sized to balance the flow rates of the cooling fluid being discharged. Inlet manifold 40 can be connected the electrode body of electrode assembly 10 with manifold openings 44 in flow communication with to inlets 30. As illustrated, manifold 40 would be attached to the electrode body of electrode assembly 10 by such means as brazing with manifold openings 44 in registration with inlets 30 of electrode assembly 10. An outlet manifold could also be provided that would be identical to inlet manifold 40 except that manifold openings 44 would be in flow communication with outlets 32 and the manifold inlet 42 would serve as a manifold outlet.

With reference to FIG. 4, an inlet manifold 50 can be provided for electrode assemblies 10′ and 12′. With additional reference to FIG. 5, a return manifold 60 is also provided. Inlet manifold 50 and return manifold 60 produce the countercurrent flow within arrangement 1′. Although not illustrated, inlet manifold 50 could be directly connected to end wall 21 of electrode assembly 10′ and return manifold could be connected to end wall 22 in a manner like that described with respect to inlet manifold 40.

Inlet manifold 50 is provided with a manifold inlet 52 for receiving the cooling fluid and a manifold outlet 54 for discharging the cooling fluid after having passed through either of the electrode assemblies 10′ or 12′. Also provided is a first set of alternating subsidiary outlets and inlets 55 and 56 which would be in flow communication with inlets 30 and outlets 32 of the electrode body of electrode assembly 10′ by being positioned in registration therewith. Internally, inlet manifold 50 is partitioned by partitions 58 and sub-partitions 59 to induce reversal of flow within inlet manifold 50 indicated by arrowheads “C”.

Return manifold 60 is connected to the opposite side of electrode assembly 10′ (or electrode assembly '12) and is provided with a second set of alternating subsidiary inlets and outlets 62 and 64 which would be in flow communication with outlets and inlets 36 and 34 of the electrode body of electrode assembly 10′ by being positioned in registration therewith. Return manifold 60 is subdivided by partitions 66 and preferably sub-partitions 68 to help induce a reversal of flow within the partitioned regions of return manifold 60.

As can be appreciated, it is possible to provide an embodiment of the present invention without the manifold arrangements described directly above. In such case, however, individual pipes and conduits would be required to supply and discharge cooling fluid from the inlets and outlets of the electrode assemblies thereof. Additionally, although not illustrated it is also possible to cascade electrode assemblies in accordance with the present invention. For instance an inlet manifold 50 could be connected to inlets 30 of electrode assembly 12. The outlets 32 of electrode assembly 10 would then be connected to the inlets 30 of electrode assembly 32. The outlets of electrode assembly 12 would then be connected to an outlet manifold having the same design as inlet manifold 50.

With reference to FIG. 6, each of the flow channels 28 can optionally be provided with a flow deflector 70 to deflect the flow towards a high voltage conductor 24 located within the electrode assembly 10. If the cavity 23 were hollow, without ribs 26, a single large flow deflector could be employed within a single flow passage provided by cavity 23 alone. An equivalent for the flow deflector would be to appropriately shape plate-like element 19 to narrow the flow area near high voltage conductor 24.

While the present invention has been described with reference to preferred embodiment, as will occur to those skilled in the art, numerous changes, additions and omissions can be made without departing from the spirit and the scope of the present invention.

1. An electrode assembly for a plasma surface treatment apparatus for treating a surface of an article comprising:
an electrode body formed of a dielectric material, the electrode body having two end walls spaced apart from one another, at least one flow channel defined between the end walls for passage of cooling fluid to cool said electrode body and configured such that a direct flow path exists for the cooling fluid from one of the two end walls to the other of the two end walls to inhibit recirculation of the cooling fluid and therefore hot spots developing in the electrode body, and openings within the end walls to introduce and discharge the cooling fluid to and from the at least one flow channel, respectively; and
a high voltage conductor located within the at least one flow passage and bounding part of the at least one flow passage so that the dielectric material forms a barrier between the surface of the article and the high voltage conductor when the electrode is in use and heat produced at the high voltage conductor is dissipated by the cooling fluid.

2. The electrode assembly of claim 1, wherein:
said electrode body further has ribs within the cavity such that the at least one flow channel is a plurality of flow channels;
said openings are arranged so that each of said flow channels has a corresponding pair of said openings for the flow of the cooling fluid within each of said flow channels.

3. The electrode assembly of claim 1, wherein the at least one flow channel is one said flow channel.

4. The electrode assembly of claim 1, wherein:
said at least one flow channel and said two end walls each have a rectangular transverse cross-section;
the high voltage conductor is of plate-like configuration; and
the openings are arranged in an array across the rectangular transverse cross-section of the two end walls.

5. The electrode assembly of claim 1, further comprising at least one flow deflector situated in said at least one flow channel to deflect the flow of the cooling fluid toward the high voltage conductor.

6. The electrode assembly of claim 2, further comprising a plurality of flow deflectors situated within said flow channels to deflect the flow of the cooling fluid toward the high voltage conductor.

7. The electrode assembly of claim 2, wherein:
said flow channels and said two end walls each have a rectangular transverse cross-section;
the high voltage conductor is of plate-like configuration; and
the openings are arranged in an array across the rectangular transverse cross-section of the two end walls.

8. The electrode assembly of claim 7, further comprising a plurality of flow deflectors situated within said flow channels to deflect the flow of the cooling fluid toward the high voltage conductor.

9. The electrode assembly of claim 1, wherein the high voltage conductor is brazed to said electrode body.

10. An arrangement of electrode assemblies for treating a substrate, said arrangement comprising:
an active electrode to which a high voltage is applied;
a ground electrode spaced from the active electrode to allow the substrate to pass therebetween;
each of the active electrode and the ground electrode formed of an electrode assembly comprising:
a electrode body formed of a dielectric material, the electrode body having two end walls spaced apart from one another and two sidewalls connecting the end walls, at least one flow channel defined between the end walls for passage of cooling fluid to cool said electrode body and configured such that a direct flow path exists for the cooling fluid from one of the two end walls to the other of the two end walls to inhibit recirculation of the cooling fluid and therefore hot spots developing in the electrode body, and openings within the end walls to introduce and discharge the cooling fluid to and from the at least one flow channel, respectively; and
a high voltage conductor located within the at least one flow passage and bounding part of the at least one flow passage so that the dielectric material forms a barrier between the surface of the article and the high voltage conductor when the electrode is in use and heat produced at the high voltage conductor is dissipated by the cooling fluid; and
the active electrode and the ground electrode sharing the sidewalls of each electrode body associated therewith to form a slot-like opening between the sidewalls and the active electrode and ground electrode.

11. The arrangement of claim 10, wherein:
said electrode body further has ribs within the cavity such that the at least one flow channel is a plurality of flow channels;
said openings are arranged so that each of said flow channels has a corresponding pair of said openings for the flow of the cooling fluid within each of said flow channels.

12. The arrangement of claim 11, wherein:
said flow channels and said two end walls each have a rectangular transverse cross-section;
the high voltage conductor is of plate-like configuration; and
the openings are arranged in an array across the rectangular transverse cross-section of the two end walls.
